(19) United States
(12) Patent Application Publication
(10) Pub. No.: US 2024/0170314 A1
(43) Pub. Date: May 23, 2024

(54) DISPLAY DEVICE MANUFACTURING APPARATUS

(71) Applicant: CONTREL TECHNOLOGY CO., LTD., Tainan City (TW)

(72) Inventors: TSAN-JEN CHEN, Tainan City (TW); WEN-I LEE, Tainan City (TW); TZU-HUNG HSU, Tainan City (TW); QING-FENG PAN, Tainan City (TW)

(21) Appl. No.: 18/509,623

(22) Filed: Nov. 15, 2023

(30) Foreign Application Priority Data
Nov. 23, 2022 (TW) 111212896
Jan. 6, 2023 (TW) 112200178

(51) Int. Cl. H01L 21/67; H01L 21/677

(52) U.S. Cl. CPC H01L 21/67288; H01L 21/67144; H01L 21/6773

(57) ABSTRACT

A display device manufacturing apparatus includes a working platform, a transferring station including a transferring gantry and a transferring welding device, a defect inspecting station including an inspecting gantry and a defect inspecting device, and a mending station including a mending gantry and a mending device. The working platform includes a plurality of pairs of conveying paths, and a plurality of carriers disposed on the plurality of pairs of conveying paths. The transferring gantry, inspecting gantry and mending gantry are disposed on the working platform and stride over the conveying paths. The transferring welding device, defect inspecting device and mending device are connected to the transferring gantry, inspecting gantry and mending gantry respectively, and movable along each gantry to the position opposite to each carrier to perform the corresponding manufacturing process to each display substrate carried by each carrier, thereby optimizing the manufacturing course and reducing waiting time.

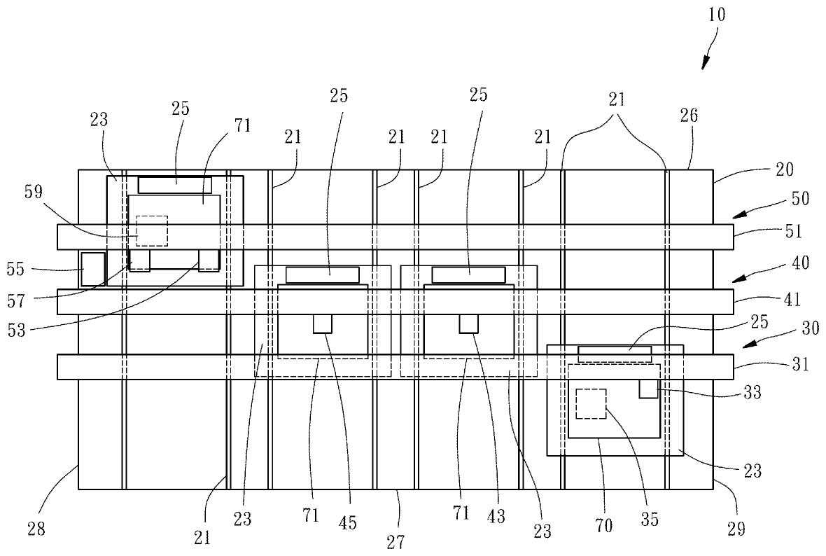

### BACKGROUND OF THE INVENTION

### 1. Field of the Invention

The present invention relates generally to display manufacturing apparatuses and more particularly, to a display device manufacturing apparatus using miniature light emitting diodes.

### 2. Description of the Related Art

The manufacture of a self-illuminating display substrate requires the transferring of a large number of miniature light emitting diodes to the display substrate for showing color of each pixel by the miniature light emitting diodes. The current manufacturing apparatus only provides the manufacturing manner of a single station, such as huge quantity of transferring, inspecting or mending. Therefore, manufacturing apparatuses of various functions are required, which need to be disposed in a relatively larger factory space, and a factory conveyance system is required for the transfer between different manufacturing processes.

Besides, currently in practice, not only the huge quantity of transferring consumes relatively more time, but the inspecting and mending also consume relatively more time. Therefore, when a specific amount of display substrates are gathered after the huge quantity of transferring and then conveyed to the inspecting station, or when the specific amount of display substrates are conveyed from the inspecting station to the mending station for the process, the display substrates need to wait in line instead of being inspected and mended efficiently.

### SUMMARY OF THE INVENTION

The present invention has been accomplished in view of the above-noted circumstances. The display device manufacturing apparatus of the present invention integrates the processes of huge quantity of transferring, inspecting and mending, enabling the inspecting and mending processes to be performed to the display substrate right after the process of huge quantity of transferring, so as to reduce the conveying distance and time, thereby raising the utility rate of the apparatus.

The display device manufacturing apparatus of the present invention includes a working platform, a transferring station, a defect inspecting station and a mending station. The working platform includes a plurality of pairs of conveying paths, and a plurality of carriers disposed on the plurality of pairs of conveying paths. The plurality of carriers are adapted to carry and test a plurality of display substrates. The transferring station is disposed on the working platform, and includes a transferring gantry and a transferring welding device. The transferring gantry strides over the plurality of pairs of conveying paths. The transferring welding device is connected to the transferring gantry, and movable along the transferring gantry. The transferring welding device is adapted to take a plurality of miniature light emitting diodes, and weld the taken plurality of miniature light emitting diodes on the plurality of display substrates located on the plurality of carriers. The defect inspecting station is disposed on the working platform, and includes an inspecting gantry and a defect inspecting device. The inspecting gantry strides over the plurality of pairs of conveying paths. The defect inspecting device is connected to the inspecting gantry, and movable along the inspecting gantry. The defect inspecting device is adapted to inspect the lighting states of the plurality of display substrates located on the plurality of carriers for inspecting the condition of the defect position of the display substrates. The mending station is disposed on the working platform, and includes a mending gantry and a mending device. The mending gantry strides over the plurality of pairs of conveying paths. The mending device is connected to the mending gantry, and movable along the mending gantry. The mending device is adapted to mend the defect position of the plurality of display substrates located on the plurality of carriers to weld at least one new miniature light emitting diode at the defect position.

As a result, the display device manufacturing apparatus of the present invention enables a plurality of display substrate producing processes, such as huge quantity of transferring, inspecting and mending, to be performed on a single apparatus at the same time. Besides, as to the transfer between different producing processes, the conveying process thereof is relatively shorter, and doesn't need the factory conveying system, so that the producing efficiency can be raised.

### BRIEF DESCRIPTION OF THE DRAWINGS

The detailed constitution, structure, features and application of the display device manufacturing apparatus will be described in the following embodiment. However, it should be understood that the following embodiment and the FIGURE are given by way of illustration only, not intended to limit the scope of the claims of the present invention, and wherein:

The sole FIGURE is a schematic view showing the constitution of the display device manufacturing apparatus of the present invention.

### DETAILED DESCRIPTION OF THE INVENTION

For the clear description of the technical program of the embodiment of the present invention or the prior art, the specific embodiment of the present invention is described hereinafter in coordination with the accompanying FIGURE. Obviously, the accompanying FIGURE of the following description is only some embodiments of the present invention. For those skilled in this field, it is easy to obtain other FIGURES according the accompanying FIGURE, and obtain other embodiments.

As shown in the sole FIGURE, the display device manufacturing apparatus 10 of the present invention includes a working platform 20, a transferring station 30, a defect inspecting station 40, and a mending station 50. The working platform 20 includes four pairs of conveying paths 21, four carriers 23, four lighting devices 25, a front side 26, a rear side 27, a left side 28, and a right side 29. The transferring station 30, the defect inspecting station 40 and the mending station 50 are disposed on the working platform 20, and located on the four pairs of conveying paths 21. The carriers 23 are disposed on the conveying paths 21, and movable along the conveying paths 21 frontward or backward.

In this embodiment, every pair of conveying paths 21 extend from the rear side 27 to the front side 26. The four pairs of conveying paths 21 are arranged apart between the left side 28 and the right side 29. By being disposed apart, the adjacent carriers 23 are prevented from collision. The lighting devices 25 are disposed on the carriers 23 for being electrically connected with display substrates 70 and 71, so as to make miniature light emitting diodes of the display substrates 70 and 71 light for functional tests. The display substrate 70 represents that in the process or having not proceeded with miniature light emitting diodes transferring. The display substrates 71 represent those already finished in miniature light emitting diodes transferring.

The transferring station 30 includes a transferring gantry 31 and a transferring welding device. The transferring gantry 31 is disposed on the working platform 20, and strides over the four pairs of conveying paths 21. The transferring welding device is disposed on the transferring gantry 31, and transversely movable along the transferring gantry 31 to the position opposite to each carrier 23 to perform a transferring welding process to the display substrate 70 carried by each carrier 23, so as to weld the taken miniature light emitting diodes on the display substrate 70.

The transferring welding device includes a transferring head 33 and a laser module 35. The transferring head 33 takes miniature light emitting diodes by a taking force, and takes a plurality of miniature light emitting diodes at a time for raising the transferring efficiency. The laser module 35 is adapted to perform the welding process to the miniature light emitting diodes attached to the display substrate 70 by the transferring head 33, so as to finish the manufacture of the display substrate.

In this embodiment, the transferring head 33 takes the miniature light emitting diodes from a wafer. In other embodiments, the miniature light emitting diodes may be carried on other bases, such as substrates, tapes, and so on.

The defect inspecting station 40 includes an inspecting gantry 41, a defect inspecting device 43, and a visual identification device 45. The defect inspecting device 43 and the visual identification device 45 are disposed on the inspecting gantry 41, and transversely movable along the inspecting gantry 41 to the position opposite to each carrier 23 to perform an inspecting process to the display substrate 71 carried by each carrier. In the inspecting process, the lighting device 25 makes the display substrate 71 light, and then the condition of the defect position of the display substrate 71 is inspected.

Wherein, the defect inspecting device 43 is adapted to inspect the condition of the defect position of the lighting display substrate 71, such as the miniature light emitting diode being relatively weaker or uneven in brightness, no light, circuit defect, or defect caused in the welding process. The visual identification device 45 is adapted to inspect the defect position of the lighting display substrate 71.

Wherein, the visual identification device 45 is, for example, API (appearance defect inspection). The defect inspecting device 43 is, for example, AOI (automated optical inspection). API is adapted for a relatively larger scope of inspection (identification) for the lighting display substrate for defining the defect position (coordinate). There may be one or more than one defect position. Because API can perform the relatively larger scope of inspection, it can inspect instantaneously to avoid a large number of defective products. AOI can focus on the defect position (coordinate) defined by API for a small scope of inspection for each defect position of the display substrate for identifying the condition of the defect relatively more correctly.

The mending station 50 includes a mending gantry 51, and a mending device. The mending device is disposed on the mending gantry 51, and transversely movable along the mending gantry 51 to the position opposite to each carrier 23 to perform a mending process to the display substrate 71 carried by each carrier. In the mending process, each defect position found by the defect inspecting station is mended correspondingly in a way that a new miniature light emitting diode is welded at the defect position to replace the defective miniature light emitting diode.

The mending device includes a mending head 53, a replacement zone 55, a removing module 57, and a laser module 59. The mending head 53 is adapted to take the miniature light emitting diode. The replacement zone 55 stores other mending heads for the replacement of the mending head 53. Every mending head 53 can take the miniature light emitting diodes of different amounts and arranged patterns. The miniature light emitting diode located at the defect position of the display substrate is removed by the removing module 57 in a removing manner of, for example, laser desoldering the miniature light emitting diode and removing the miniature light emitting diode, or directly breaking the miniature light emitting diode by laser. The laser module 59 is adapted to perform a welding process to the miniature light emitting diode attached to the defect position.

The transferring gantry 31, the inspecting gantry 41 and the mending gantry 51 are transversely arranged apart. In short, each pair of paths 21 and each gantry have a perpendicular relation in extending direction thereof, so that the transferring welding device, the defect inspecting device 43, the visual identification device 45 and the mending device are movable to the position opposite to each carrier 23 through the gantries to perform the associated manufacturing processes.

The arrangement of the display device manufacturing apparatus 10 of the present invention is described above, and the application thereof is described below. Each carrier 23 can individually carry the respective product, i.e. the display substrate 70 or 71.

In the transferring station 30, the transferring head 33 is movable along the transferring gantry 31 to the position opposite to the display substrate 70 located on the rightmost carrier 23 for attaching the miniature light emitting diodes of the transferring head 33 to the corresponding positions of the display substrate 70. Then, the welding process is performed to the miniature light emitting diodes attached on the display substrate 70 by the laser module 35, so that the transferring of the miniature light emitting diodes onto the display substrate is finished.

After that, the display substrate, onto which the transferring station 30 finishes transferring the miniature light emitting diodes, is moved frontward along with the carrier 23 to wait for the inspection performed by the defect inspecting device 43 and the visual identification device 45 of the defect inspecting station 40. In the inspecting process, the lighting device 25 on the carrier 23 automatically makes the display substrate 71 light for the visual identification device 45 to perform the inspection and identification for defining the defect position (coordinate) of the display substrate 71 and the amount thereof. Then, detailed inspection is performed to each defect position defined by the visual identification device 45. The digital camera (charge coupled device, CCD) of the defect inspecting device 43 is adapted to inspect the relation between the miniature light emitting diodes of the display substrate 71 and the defect of the display substrate 71, so as to find out the problem of the defect, such as broken miniature light emitting diodes, circuit defect or others.

In this embodiment, the relatively larger scope of inspection is performed by the visual identification device 45 to efficiently determine the defect existing in the display substrate 71. Then, the detailed inspection is performed by the defect inspecting device 43 to determine the problem of the defect. However, in other embodiments, the visual identification device 45 can be omitted, and the defects are inspected by the defect inspecting device 43 one by one.

After the inspection is finished, the carrier 23 carrying the display substrate 71 is moved frontward again to wait for the mending station 50 to perform the corresponding mending process according to the defect of the display substrate 71. The mending device can choose the appropriate mending head 53 from the replacement zone 55 and take the new miniature light emitting diode to reattach it at the defect position of the display substrate 71 for the laser module 59 to perform the laser welding, so that the new miniature light emitting diode is welded at the defect position and the mending is finished. At last, the lighting device 25 can make the mended display substrate 71 light again to confirm whether the mending is completed or not.

Wherein, the mending head 53 takes the new miniature light emitting diode from the wafer. Compared with the aforementioned miniature light emitting diodes taken by the transferring head 33, the mending head 53 can take the rest of the miniature light emitting diodes on the wafer after the process performed by the transferring station 30, so as to raise the utility rate of the miniature light emitting diodes of the wafer and reduce the material waste.

In other embodiments, the mending device can remove the miniature light emitting diode located at the defect position by the removing module 57 to spare the welding pad located at the defect position. After that, the appropriate mending head 53 is chosen to take the new miniature light emitting diode and then reattach it at the defect position of the display substrate for the laser module 59 to perform the laser welding, so that the new miniature light emitting diode is welded at the defect position and the mending is finished. At last, the lighting device 25 can make the mended display substrate light again to confirm whether the mending is completed or not.

As a result, by the display device manufacturing apparatus of the present invention, the miniature light emitting diodes can be transferred onto the display substrate, inspected and mended on a single apparatus, so that the production is performed efficiently. Besides, the time for waiting for the materials at each working station can be reduced, so that the producing course of the display device is optimized effectively.

What is claimed is:

1. A display device manufacturing apparatus comprising:
a working platform comprising a plurality of pairs of conveying paths, and a plurality of carriers disposed on the plurality of pairs of conveying paths, the plurality of carriers being adapted to carry and test a plurality of display substrates;
a transferring station disposed on the working platform and comprising a transferring gantry and a transferring welding device, the transferring gantry striding over the plurality of pairs of conveying paths, the transferring welding device being connected to the transferring gantry and movable along the transferring gantry, the transferring welding device being adapted to take a plurality of miniature light emitting diodes and weld the taken plurality of miniature light emitting diodes on the plurality of display substrates located on the plurality of carriers;
a defect inspecting station disposed on the working platform and comprising an inspecting gantry and a defect inspecting device, the inspecting gantry striding over the plurality of pairs of conveying paths, the defect inspecting device being connected to the inspecting gantry and movable along the inspecting gantry, the defect inspecting device being adapted to inspect lighting states of the plurality of display substrates located on the plurality of carriers for inspecting condition of a defect position of the plurality of display substrates; and
a mending station disposed on the working platform and comprising a mending gantry and a mending device, the mending gantry striding over the plurality of pairs of conveying paths, the mending device being connected to the mending gantry and movable along the mending gantry, the mending device being adapted to mend the defect position of the plurality of display substrates located on the plurality of carriers to weld at least one new miniature light emitting diode at the defect position.

2. The display device manufacturing apparatus as claimed in claim 1, wherein the working platform comprises a front side, a rear side, a left side and a right side; every said pair of conveying paths extend from the rear side to the front side; the plurality of pairs of conveying paths are arranged apart between the left side and the right side; the transferring gantry, the inspecting gantry and the mending gantry are arranged apart between the front side and the rear side.

3. The display device manufacturing apparatus as claimed in claim 1, wherein the defect inspecting station further comprises a visual identification device; the visual identification device is disposed on the inspecting gantry for defining the defect position of the plurality of display substrates which light.

4. The display device manufacturing apparatus as claimed in claim 3, wherein a scope of inspection of the visual identification device is larger than a scope of inspection of the defect inspecting device.

5. The display device manufacturing apparatus as claimed in claim 1, wherein the working platform comprises a plurality of lighting devices for being disposed on the plurality of carriers for testing the plurality of display substrates.
